(19) United States
(12) Patent Application Publication
(10) Pub. No.: US 2005/0094457 A1
(43) Pub. Date: May 5, 2005

(54) Ferroelectric memory and method of operating same

(75) Inventors: Zheng Chen, Colorado Springs, CO (US); Vikram Joshi, Colorado Springs, CO (US); Narayan Solayappan, Colorado Springs, CO (US); Carlos A. Paz de Araujo, Colorado Springs, CO (US); Larry D. McMillan, Colorado Springs, CO (US)

Correspondence Address: PATTON BOGGS, 1660 LINCOLN ST, SUITE 2050, DENVER, CO, 80264, US

(73) Assignee: Symetrix Corporation, Colorado Springs, CO (US)

(21) Appl. No.: 10/425,257

(22) Filed: Apr. 28, 2003

Related U.S. Application Data
(63) Continuation-in-part of application No. 10/009,470, filed on Apr. 22, 2002, now abandoned.

(30) Foreign Application Priority Data
Jun. 10, 1999 (US) 09329670
Aug. 30, 1999 (US) 09385308
Mar. 10, 2000 (US) 09523492

(51) Int. Cl. G11C 7/00

(52) U.S. Cl. 365/222

(57) ABSTRACT

A ferroelectric memory includes a group of memory cells, each cell having a ferroelectric memory element, a drive line on which a voltage for writing information to the group of memory cells is placed, and a bit line on which information to be read out of the group of memory cells is placed. The memory is read by placing a voltage less than the coercive voltage of the ferroelectric memory element across a memory element. A preamplifier is connected between the memory cells and the bit line. A set switch is connected between the drive line and the memory cells, and a reset switch is connected to the memory cells in parallel with the preamplifier. Prior to reading, noise from the group of cells is discharged by grounding both electrodes of the ferroelectric memory element.

### RELATED APPLICATIONS

This application is a continuation-in-part of U.S. patent application Ser. No. 10/381,235 filed Mar. 20, 2003 with an effective filing date of Sep. 25, 2001, which is a national phase filing of PCT Application No. PCT/US01/42288 filed Sep. 25, 2001, which claims the benefit of U.S. Provisional Application Ser. No. 60/235,241 filed Sep. 25, 2000. This application is also a continuation-in-part of U.S. patent application Ser. No. 10/009,470 filed Jun. 12, 2000, which is itself a continuation-in-part of U.S. patent application Ser. No. 09/329,670 filed Jun. 10, 1999, now U.S. Pat. No. 6,339,238, which is itself a continuation-in-part of U.S. patent application Ser. No. 09/170,590 filed Oct. 13, 1998, now U.S. Pat. No. 6,441,414. All of the above patents and patent applications are hereby incorporated by reference as though fully disclosed herein.

### BACKGROUND OF THE INVENTION

1. Field of the Invention

This invention relates to ferroelectric memories, and more particularly to such a memory and method of operation that has very low fatigue, can be used in a non-destructive read mode, and eliminates disturb problems.

2. Statement of the Problem

It has been known since at least the 1950's that if a practical ferroelectric memory could be made, it would provide a fast, dense, non-volatile memory that could be operated at relatively low voltages. See Orlando Auciello et al., “The Physics of Ferroelectric Memories”, Physics Today, July 1998, pp. 22-27. The principal type of ferroelectric memory being explored today is the non-volatile ferroelectric random access memory, or NVFRAM. Ibid. A disadvantage of the NVFRAM is that, in the process of reading it, the information it holds is destroyed and, therefore, the read function must be followed by a rewrite function. However, it has been postulated for at least 40 years that it may be possible to design a memory in which the memory element is a ferroelectric field effect transistor (FET), which memory could be non-destructively read. See Shu-Yau Wu, “A New Ferroelectric Memory Device, Metal-Ferroelectric-Semiconductor Transistor”, IEEE Transactions On Electron Devices, pp. 499-504, August 1974; S. Y. Wu, “Memory Retention and Switching Behavior Of Metal-Ferroelectric-Semiconductor Transistors”, Ferroelectrics, Vol. 11, pp. 379-383, 1976; and J. R. Scott, C. A. Paz de Araujo, and L. D. McMillan, “Integrated Ferroelectrics”, Condensed Matter News, Vol. 1, No. 3, pp. 15-20, 1992. Because the ferroelectric memory effect measured in the early devices of Wu was only a temporary, single-state effect rather than a long-lived two-state effect, it is now believed that this effect was charge injection effect rather than an effect due to ferroelectric switching. However, a metal-ferroelectric-insulator-semiconductor FET device, i.e., a MFISFET, has recently been reported that appears to show true ferroelectric memory behavior. See Tadahiko Hirai et al., “Formation of Metal/Ferroelectric/Insulator/Semiconductor Structure With A CeO₂ Buffer Layer”, Japan Journal of Applied Physics, Vol. 33, Part I, No. 9B, pp. 5219-5222, September 1994; Tadahiko Hirai et al., “Characterization of Metal/Ferroelectric/lnsulator/Semiconductor Structure With A CeO₂ Buffer Layer”, Japan Journal of Applied Physics, Vol. 34, Part I, No. 8A, pp. 4163-4166, August 1995; Yong Tae Kim et al., “Memory Window of Pt/SrBi₂Ta₂O₉/CeO₂/SiO₂/Si Structure For Metal Ferroelectric Insulator Semiconductor Field Effect Transistor”, Applied Physics Letters, Vol. 71, No. 24, pp. 3507-3509, 15 Dec. 1997; and U.S. Pat. No. 5,744,374 issued Apr. 28, 1998 to Jong Moon.

To make a memory requires not only a memory element, but also a means for addressing a large number of memory elements. Initially, it was believed that a ferroelectric memory element might be addressed by a simple array of rows and columns of conductors. A ferroelectric memory element, it was thought, could be located at each of the junctures of the array and addressed by applying a voltage to the conductors for the corresponding row and column. It was believed that if the voltage on each conductor was less than the threshold voltage for ferroelectric switching (coercive voltage) and the voltage difference between the conductors was greater than the coercive voltage, then only the selected cell would be written to or read, and the other cells would remain unchanged. However, it was found that this did not work because the neighboring unselected cells were disturbed by the voltages on the address lines. Thus, a switch was added between one of the address lines and each ferroelectric memory element. See U.S. Pat. No. 2,876,436 issued Mar. 3, 1959 to J. R. Anderson and U.S. Pat. No. 4,873,664 issued Oct. 10, 1989 to S. Sheffield Eaton, Jr. If the switch is a transistor as in the latter patent, the memory assumes a memory address architecture essentially the same as that of a conventional DRAM. However, when applied to a ferroelectric memory, even this architecture disturbed the memory cells attached to the same plate line as the addressed cell. That is, it has been found that ferroelectric materials do not have a sharp coercive threshold voltage, but rather even a small voltage will cause the ferroelectric to partially switch and, therefore, the repetitive application of small disturb voltages, such as occur in a conventional memory array, eventually causes the change or loss of a memory state. Therefore, a more complex architecture was proposed to overcome this disturb. See, for example, U.S. Pat. No. 4,888,733 issued December 19, 1989 to Kenneth J. Mobley.

The above address schemes are all for a NVFRAM; that is, a memory utilizing a ferroelectric capacitor as a memory element, rather than for a memory utilizing a ferroelectric FET. A number of address architectures have been disclosed up to now for a memory in which the memory element is a ferroelectric FET. U.S. Pat. No. 5,523,964 issued Jun. 4, 1996 to McMillan et al. discloses a relatively complex addressing architecture, utilizing five transistors in each memory cell in addition to the ferroelectric FET. This complexity is incorporated, like the Mobley architecture, to avoid the disturb problem. Such complex architecture results in a memory that is much less dense and slower than, for example, a conventional DRAM. An architecture that uses one ferroelectric FET per memory cell has been proposed, but has not been implemented because it cannot be read properly if three neighboring cells all are in the conducting logic state. See U.S. Pat. No. 5,449,935 issued to Takashi Nakamura on Sep. 12, 1995, column 3, line 56—column 4, line 15. Another such one-FET-per-memory cell design has been proposed in U.S. Pat. No. 5,768,185 issued to Takashi Nakamura and Yuichi Nakao on Jun. 16, 1998. However, during reading a voltage of 3V (volts) to 5V is applied to the word line while the ground or 0V is applied to the bit line. While this is not enough to switch the ferroelectric in a single read cycle, as indicated above, it is now known that successive pulses of this magnitude, such as occur in a memory in the normal process of reading, can disturb the ferroelectric state. In addition, since the bit line is connected to the source and substrate and the word line is connected to the gate, if the WLn and BLm+1 signals are not exactly synchronized, the erase process of one cell will disturb the next. Under manufacturing specifications that are practically feasible, such exact synchronization is difficult to achieve in all cells. Therefore, in a commercial product, there will be short disturb voltages during the erase cycle also. Further, with this architecture, it is not possible to write a byte at a time, which is a much faster way of writing in a ferroelectric FET. Thus, the fact that the ferroelectric material does not have a sharp coercive field threshold and can be switched by repetitive applications of a voltage somewhat less than the coercive voltage has made several of the original objectives of research into ferroelectric memories unattainable. It would, therefore, be highly desirable to provide an architecture and method for addressing a ferroelectric memory, particularly a ferroelectric FET structure and method of making the structure, that was relatively simple and, at the same time, avoided the problems in the prior art, such as the disturb problem.

### SUMMARY OF THE INVENTION

The invention solves the above problem by providing a method and apparatus for addressing a ferroelectric memory in which fatigue and disturb are insignificant. Commercial forms of the memory can easily operate without fatigue or disturbance for ten years or more. The invention does this by combining a set and reset switch with a group of memory cells, such as a column or row. Preferably, the invention also utilizes the combination of a read voltage that is less than the coercive voltage with a preamplifier associated with each group of cells. Preferably, the read voltage is less than half the coercive voltage, and, in some cases, is less than a third of the coercive voltage.

The invention provides a ferroelectric memory comprising a memory cell and a circuit for reading and writing to the memory cell wherein the circuit for reading and writing includes a drive line on which a voltage for writing information to the memory cell is placed, a bit line on which information to be read out of the memory cell is placed, a preamplifier between the memory cell and the bit line, a set switch connected between the drive line and the memory cell, and a reset switch connected to the memory cell. Preferably, the preamplifier comprises a transistor having a gate and a pair of source-drains, and wherein the memory cell is connected to the gate, and one of the source-drains is connected to the bit line. Preferably, the reset switch is a transistor having a pair of reset source-drains, with one of the reset source-drains connected to the memory cell and the other of the reset source-drains connected to one of the source-drains of the preamplifier transistor. Preferably, the set switch is a transistor having a pair of set source-drains, with one of the set source-drains connected to the memory cell and the other of the set source-drains connected to the drive line. Preferably, the reset switch is a transistor having a pair of reset source-drains, with one of the reset source-drains connected to the memory cell and the other of the reset source-drains connected to the bit line. Preferably, the reset switch is connected in parallel with the preamplifier between the memory cell and the bit line.

In another aspect, the invention provides a ferroelectric memory comprising a memory cell and a circuit for reading and writing to the memory cell wherein the circuit for reading and writing includes a drive line on which a voltage for writing information to the memory cell is placed, a bit line on which information to be read out of the memory cell is placed, a preamplifier between the memory cell and the bit line, a set switch connected between the drive line and the memory cell, and a reset switch connected in parallel with the preamplifier between the memory cell and the bit line. Preferably, the preamplifier comprises a transistor having a gate and a pair of source-drains, and wherein the memory cell is connected to the gate, and one of the source-drains is connected to the bit line. Preferably, the set switch is a transistor having a pair of set source-drains, with one of the set source-drains connected to the memory cell and the other of the set source-drains connected to the drive line. Preferably, the reset switch is a transistor having a pair of reset source-drains, with one of the reset source-drains connected to the memory cell and the other of the reset source-drains connected to the bit line.

Preferably, each of the ferroelectric memories herein described can be implemented either as a non-destructive read out memory or a destructive read out memory.

The invention also provides a method of reading a ferroelectric memory, the memory including: a memory cell including a ferroelectric memory element having a coercive voltage, and a conducting line connected to the memory cell, the method comprising the steps of: placing a voltage across the ferroelectric memory element, the voltage being less than the coercive voltage; and sensing a voltage on the conducting line. Preferably, the voltage ranges from 0.1V to 0.5V, and most preferably, from 0.1V to 0.3V. Preferably, the voltage is one-half of the coercive voltage or less. In some designs, the voltage is one-third of the coercive voltage or less. Preferably, the memory includes a group of memory cells connected to the conducting line and further including a reset step comprising discharging noise from the group of memory cells. Preferably, each of the memory elements comprises a ferroelectric capacitor and the reset step comprises grounding both sides of each of the ferroelectric capacitors in the group of memory cells.

In a further aspect, the invention provides a method of reading a ferroelectric memory, the memory including: a memory cell including a ferroelectric memory element and a conducting line connected to the memory cell, the method comprising the steps of: placing a first voltage across the ferroelectric memory element to develop a read voltage on the conducting line; preamplifying the read voltage to produce a preamplified voltage or current on a bit line; and sensing the preamplified voltage or current on the bit line. Preferably, the first voltage ranges from 0.1V to 0.5V. Most preferably, the first voltage ranges from 0.1V to 0.3V. Preferably, the first voltage is one-half or less of the coercive voltage of the ferroelectric memory element. In some designs, the first voltage is one-third or less of the coercive voltage of the ferroelectric memory element.

The invention further provides a method of discharging noise from a ferroelectric memory, the memory including a group of memory cells, each memory cell including a ferroelectric capacitor, the method comprising grounding both sides of each of the ferroelectric capacitors.

The invention not only provides a ferroelectric memory in which one cell is not disturbed when another cell is written to or read and can be read non-destructively, but also is simpler and much more dense than state-of-the-art commercial ferroelectric memories. Numerous other features, objects and advantages of the invention will become apparent from the following description when read in conjunction with the accompanying drawings.

### BRIEF DESCRIPTION OF THE DRAWINGS

FIG. 1 shows an electrical schematic diagram of a preferred embodiment of a ferroelectric memory according to the invention;

FIG. 2 is an equivalent circuit diagram of the ferroelectric memory of FIG. 1 during a NDRO operation;

FIG. 3 illustrates a graph of the polarization versus voltage, i.e., the hysteresis loop for a memory according to the invention during the NDRO read operation;

FIG. 4 is a circuit diagram of a preferred architecture of an NDRO ferroelectric memory according to the invention;

FIG. 5 is a circuit diagram of an alternative preferred architecture of an NDRO ferroelectric memory according to the invention;

FIG. 6 is a circuit diagram of another alternative architecture of an NDRO ferroelectric memory according to the invention;

FIG. 7 is a an alternative embodiment of the memory of FIG. 6;

FIG. 8 is an electrical block diagram of a typical integrated circuit memory in which the memory array systems 200, 300, 400, and 500 according to the invention may be used;

FIG. 9 is a circuit diagram of another alternative architecture according to the invention illustrating an alternative arrangement of the signals applied to the reset switch and the preamplifier;

FIG. 10 is an electrical circuit diagram showing the essential elements of a memory cell according to an alternative preferred embodiment of the invention and their connection to the signal lines;

FIG. 11 shows a cross-sectional view of a preferred embodiment of a ferroelectric FET according to the invention; and

FIG. 12 shows a 2×2 cell array of a memory according to the invention.

### DETAILED DESCRIPTION OF THE PREFERRED EMBODIMENT

1. Introduction

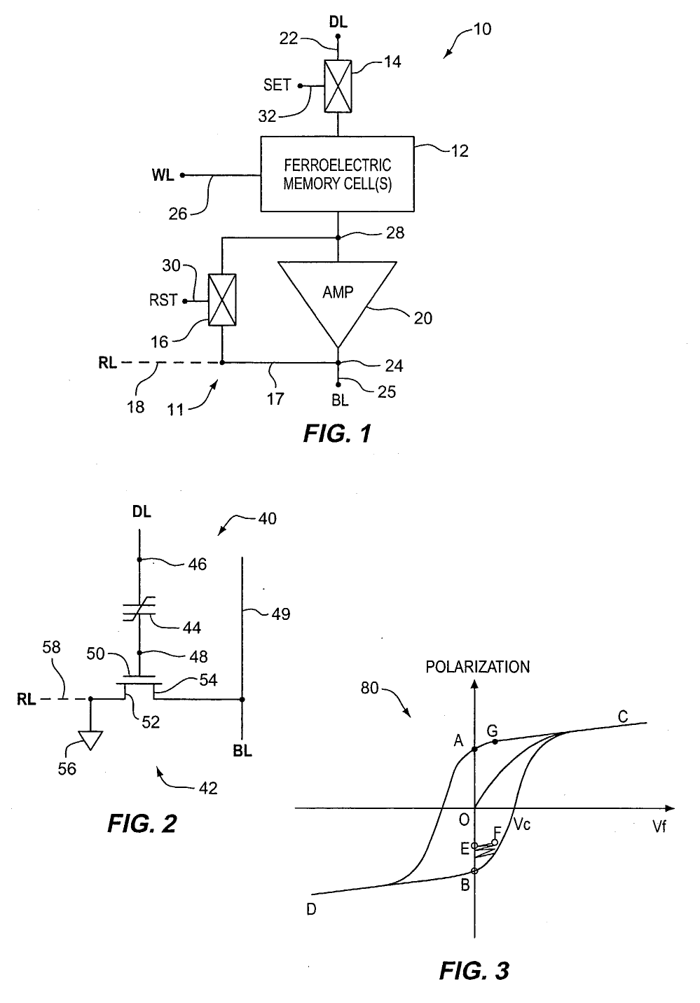

As known in the art, the coercive voltage of a ferroelectric memory element is a voltage that is high enough to cause the memory element to switch ferroelectric states. In the prior art, ferroelectric memories have been read by placing a voltage that is equal to or higher than the coercive voltage across the ferroelectric memory element, and then reading a voltage created on a bit line connected to the memory element. Examples of ferroelectric memories that can be read by placing a voltage less than the coercive voltage across the memory element are given in the parent patent applications recited in the Related Applications section above. A preferred embodiment of a ferroelectric memory cell array that can be read using a voltage less than the coercive voltage is shown in FIG. 1.

FIG. 1 shows a general structure of a ferroelectric memory array system 10 according to this invention. Array system 10 includes memory cell or cells 12, set switch 14, reset switch 16, and preamplifier 20. Memory cell group 12 is preferably a ferroelectric plurality of memory cells, but may be a single cell. The cell may be any ferroelectric cell, and examples are given below. Reset switch 16 and preamplifier 20 are connected in parallel between bit line node 24 and memory cell/preamplifier node 28. Set switch 14 is connected in series between drive line 22 and memory cell group 12. Switches 14 and 16 are controlled by the SET and RST signals on lines 32 and 30, respectively.

As will be understood more fully after reading the description below, in this disclosure, the term “preamplify” or “amplify” includes increasing a voltage to permit it to be read more easily, increasing a current so that it can be read more easily, changing a voltage that cannot be easily read to a current that can be more easily read, and changing a current that cannot be easily read to a voltage that can be more easily read.

The dashed line 18 carrying the signal RL illustrates an alternative arrangement of the signals applied to reset switch 16 and preamplifier 20. In this alternative arrangement, line 17 between the bit line and reset switch 16 is eliminated and replaced by line 18. In this arrangement, preamplifier 20 would have an internal connection to ground that is not explicitly shown, or could also be connected to the RL signal. This arrangement is a little more complex since it requires another signal, RL, but it permits separating the signals for the reading and writing functions, which adds a degree of control on robustness to the circuit.

In the preferred arrangement, digital “1” and “0” states are written via drive line 22 and bit line 25 on which the signals DL and BL, respectively, are placed. Data is read via bit line 25, with a low operation voltage applied on drive line 22. Alternatively, data may be read via drive line 22 with a low operation voltage applied on bit line 25. A signal WL is applied to memory cell array 12 via a word line 26 to select the memory cell to be written to or read. Table 1 shows the truth table of write and read operations. During writing operation, switches 14 and 16 are both ON. Data “1” is programmed by applying a high voltage on DL, while BL is grounded. The high voltage is a voltage greater than the coercive voltage, Vcc, of the ferroelectric memory element in cell(s) 12. Data “0” is programmed by applying a high voltage on BL, while DL is grounded.

TABLE 1
Truth Table of Write/Read Operations

| | DL | BL | Set Switch | Reset Switch |
|---|---|---|---|---|
| Write “1” | 1 | 0 | ON | ON |
| Write “0” | 0 | 1 | ON | ON |
| Read | A low voltage | Sensing | ON | OFF |

During the reading operation, set switch 14 is ON while reset switch 16 is OFF. Therefore, the selected cell is equivalent to the circuit shown in FIG. 2. As illustrated In FIG. 2, a transistor 42 is preferably used as a preamplifier and a ferroelectric capacitor 44 is preferably used as the ferroelectric element. Transistor 42 may be called a “read transistor” since it is used in the reading operation. It is preferably a MOSFET. In this embodiment, during the read operation, one electrode of capacitor 44 is equivalently connected to drive line node 46, and the other electrode is equivalently connected to memory cell/preamplifier node 48, which is also connected to gate 50 of transistor 42. One source-drain 54 of transistor 42 is equivalently connected to bit line 49, while the other source-drain 52 is equivalently connected to low voltage, indicated as a ground 56.

The reading and writing functions for the alternative arrangement using line 18 and the signal RL are the same, except that the RL signal replaces the BL signal in the write function. In this alternative arrangement, the other source-drain 52 is connected to the RL signal, which would be set to low or ground during the reading operation.

A relatively low DL voltage is applied to drive line node 46 during reading, which voltage is used to differentiate the status of ferroelectric capacitor 44. The voltage across ferroelectric capacitor 44 can be found by:
V₁=V_{f}+V_{MOS} (Equation 1)
C_{f}V_{f}=C_{MOS}V_{MOS} (Equation 2)
where V₁ is the voltage applied on node 46; V_{f} is the voltage across the ferroelectric capacitor, V_{MOS} is the voltage on node 48 or gate 50 of transistor 42; C_{f} is the ferroelectric capacitance; and C_{MOS} is the total MOS capacitance of transistor 42 from gate to substrate. Therefore, the C_{f} and C_{MOS} ratio plays an important role in this circuit. The voltage on node 46, V₁, and this ratio must ensure that the voltage dropped across the ferroelectric capacitor, or V_{f}, is not high enough to disturb the ferroelectric status.

The read voltage DL is preferably 0.5V to 3.0V, and most preferably 0.7V to 2.6V. As an example, say 1.2V is applied to drive line node 46. A proper C_{f} and C_{MOS} ratio is chosen so that only 0.1V to 0.3V drops across the ferroelectric capacitor. This small positive voltage is well below the coercive voltage and is not enough to disturb the “0” state of the ferroelectric capacitor. Because of the different ferroelectric capacitance between the “1” state and the “0” state, a different voltage, VMOS, will develop on the gate of read transistor 42 if ferroelectric capacitor 44 is in the “1” state than if the ferroelectric capacitor is in the “0” state. Preferably, a voltage between 0.1V and 1.0 V is applied to bit line 49, and typically this voltage is 0.5 V. The voltage difference between ground 56 and bit line 49 causes a drain-to-source current to flow through transistor 42, which current will be different depending on the voltage on gate 50. Thus, the small voltage differences in the gate voltage between the “0” and “1” states results in different drain-to-source currents, which are read by conventional sense amplifier circuitry of the memory.

If the cell is programmed with data “0”, the ferroelectric is in state B as shown in FIG. 3. During reading operation, a positive voltage drops across the ferroelectric, and its value can be determined by Equations (1) and (2). If this positive voltage is lower than the coercive voltage, it could destroy part of the negative polarization, but will not switch the polarization. As shown in FIG. 3, state B would increase with the positive pulses of multiple reading cycles, but it will stop at some point E, which depends on how much voltage is applied and the number of cycles applied. Therefore, in general, for reading data “0” operation and a voltage DL between 0.5V to 3.0V, the polarization changes between state E and state F.

If the cell is programmed with data “1”, the ferroelectric is in state A as shown in FIG. 3. A positive reading voltage will not disturb this positive polarization at all. Therefore, for reading data “1” operation, the polarization changes between state A and state G.

Returning to Equations (1) and (2), to differentiate data “1” and “0”, a different C_{f} is required for the two states. C_{f} is the ferroelectric capacitance, or approximately dP/dV_{f}, which is the slope of the polarization. Therefore, the difference between the slope of the AG curve and the slope of the EF curve in FIG. 3 is used to differentiate data “1” and “0”. Usually, the slope of AG is smaller than that of EF, which means C_{f} of data “1” is smaller than C_{f} of data “0”. The difference of C_{f} can be sensed by either voltage or current sense.

Each time the ferroelectric element is read, only a small voltage is applied to the ferroelectric film, and the ferroelectric will not switch. Therefore, this invention eliminates the fatigue problem, if we assume that the number of reading cycles is much greater than the number of writing cycles, which is true for most memory applications.

This invention can also be used as destructive read out memory if a high voltage is applied to drive node 46 during the reading operation. In this case, for the “0” state, the polarization may return back to the origin “0” or state A as shown in FIG. 3. A writing back procedure should be followed after each read. Using a destructive read out operation, the noise margin can be improved.

2. Detailed Architectures

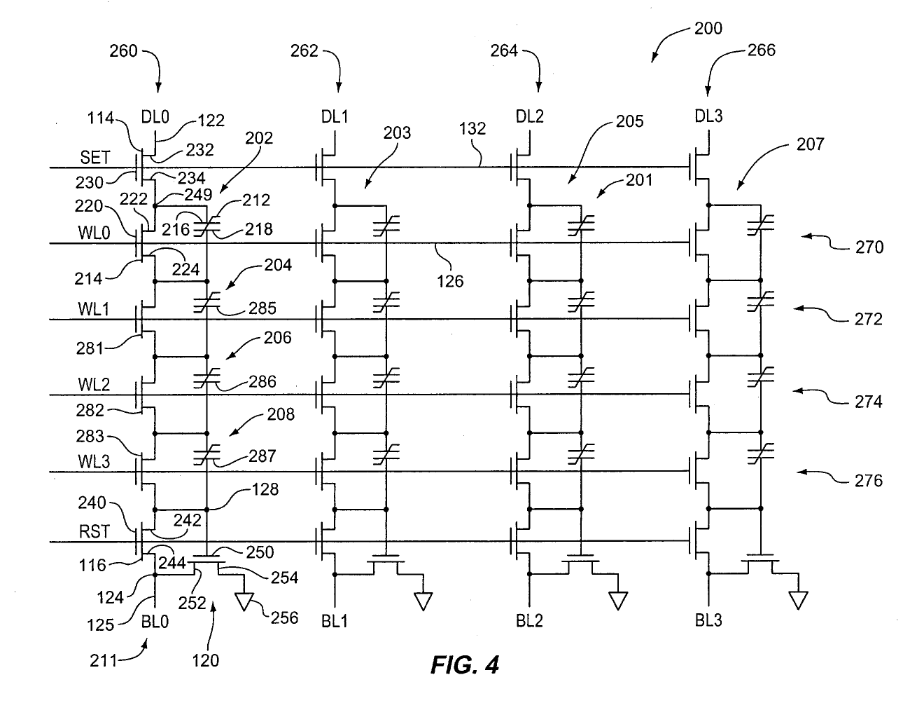

FIGS. 4-7 illustrate the invention as used in combination with various memory cell architectures. FIG. 4 illustrates the preferred embodiment of the invention utilizing a chain cell architecture. In this embodiment, a 4×4 cellular array 201 is shown. That is, there are four columns 260, 262, 264, and 266 of cells and four rows 270, 272, 274, and 276 of cells. For example, column 260 comprises cells 202, 204, 206, and 208, while row 270 comprises cells 202, 203, 205, and 207. Each cell, such as 202, includes a transistor, such as 214, and a capacitor, such as 212. In each cell, the transistor is connected in parallel with the capacitor. That is, one source-drain 222 of transistor 214 is connected to one electrode 216 of capacitor 212, while the other source-drain 224 is connected to the other electrode 218 of capacitor 212. Gate 220 of transistor 214 is connected to word line 126. The cells, such as 202, 204, 206, and 208 of a column, such as 260, are connected in series, hence the name “chain cell”. In this architecture, the transistors of neighboring cells in the chain are connected source to drain, and the capacitors of neighboring cells are connected electrode to electrode. Cell 202 at the end nearest drive line 122 is connected to one source-drain 234 of set transistor 114, while the other source-drain 232 is connected to drive line 122. Gate 230 of set transistor 114 is connected to set signal line 132. Cell 208 at the end closest to bit line 125 is connected to gate 250 of amplifying transistor 120, and reset transistor 116 is connected across preamplifier 120, with one source-drain 242 connected to gate 250 and the other source-drain 244 connected to source-drain 252 of amplifying transistor 120 that is connected to bit line 125. The other source-drain 254 of amplifying transistor 120 is connected to ground 256. The operation of the memory array system 200 is the same as that described above with respect to FIG. 1, with node 124 in FIG. 4 corresponding to node 24 in FIG. 1, node 128 in FIG. 4 corresponding to node 28 in FIG. 1, set transistor 114 of FIG. 4 corresponding to set switch 14 of FIG. 1, reset transistor 116 of FIG. 4 corresponding to reset switch 16 of FIG. 1, and amplifying transistor 120 of FIG. 4 corresponding to preamplifier 20 of FIG. 1. The only additional factor that must be considered is that the word line, such as 126, of the row of the selected cells are held low to hold the transistor, such as 214, of the selected cell off, while the word lines of the non-selected cells are held high to turn the corresponding transistors on and short out the corresponding capacitor. The set transistor, such as 114, of the selected column, such as 260, is on while the other set transistors of the non-selected columns are off.

In the chain cell architecture, the cells are connected in series, which reduces the internal connections to a minimum and therefore reduces the cell size. With a longer chain of cells, the average cell size becomes even smaller.

Table 2 is a truth table for writing and reading cell 10, that is, the cell in row “1” and column “0”, i.e., cell 204. Since the zeroth column is selected, DL1, DL2, DL3, BL1, BL2, and BL3 are all low or at zero voltage, and do not change. In this table, WL1 is the word line signal for the cells in row “1”, WLx is the word line signal for the xth row, DL0 and BL0 are the drive line and bit line signals, respectively, for the zeroth column, and SET0 and RST0 are the SET and RST signals, respectively, for the zeroth column. To select a certain cell, the signal WL applied to its word line must be a low voltage, assuming all transistors are NMOS, to turn off its cell transistor, while all other WLs must be high. For example, to write or read cell 10, WL1 must be low to turn off the transistors in that row, while WL0, WL2, and WL3 are all high so that the transistors in the corresponding rows are on, which shorts the nodes between the transistors. In such a case, all the voltage between nodes 249 and 128 will drop across selected cell 204, and the other three ferroelectric capacitors are all shorted; that is, there is no voltage drop across those three capacitors.

TABLE 2
Truth Table of Write/Read Cell 10 of Chain Cell

| | WL1 | WLx | DL0 | BL0 | SET0 | RST0 |
|---|---|---|---|---|---|---|
| Write “1” | 0 | 1 | 1 | 0 | 1 | 1 |
| Write “0” | 0 | 1 | 0 | 1 | 1 | 1 |
| Read | 0 | 1 | Low Voltage | 0 | 1 | 0 |

To write “1” to cell 10, DL0 is set to the digital “1” state, which is about 3V, and BL0 is set at low or 0V. SET0 and RST0 are both at the digital “1” state, approximately 3V, turning on transistors 114 and 116, so that 3V is applied to node 249 while node 128 is grounded. Because transistors 214, 282, and 283 are all turned on by applying 3V to WL0, WL2, and WL3 while transistor 281 is off by applying 0V to WL1, the 3V between node 249 and node 128 goes directly to the top electrode and bottom electrode of ferroelectric capacitor 285, or a data “1” is written into capacitor 285. If the coercive voltage of the ferroelectric capacitor is about 1V, 3V is enough to switch the ferroelectric.

Writing “0” is very similar to writing “1”, except that SET0 is 0V while RST0 is 3V.

To read cell 10, the “1” row is selected by applying a low WL signal turning off transistor 281, while keeping all other word line signals WLx high to turn transistors 214, 282, and 283 on. SET0 is high to turn on set transistor 114, which lets a low voltage of about 0.5V applied on DL0 go through to the chained cells. Because transistor 281 is off while transistors 214, 282, and 283 are all on, the voltage applied on DL0 will go to capacitor 285, and capacitors 218, 286, and 287 are shorted. The voltage applied to capacitor 285 causes a voltage to be applied to node 128 as described above with respect to FIGS. 2 and 3, which voltage is sensed and converted to current by transistor 120 and read via the bit line.

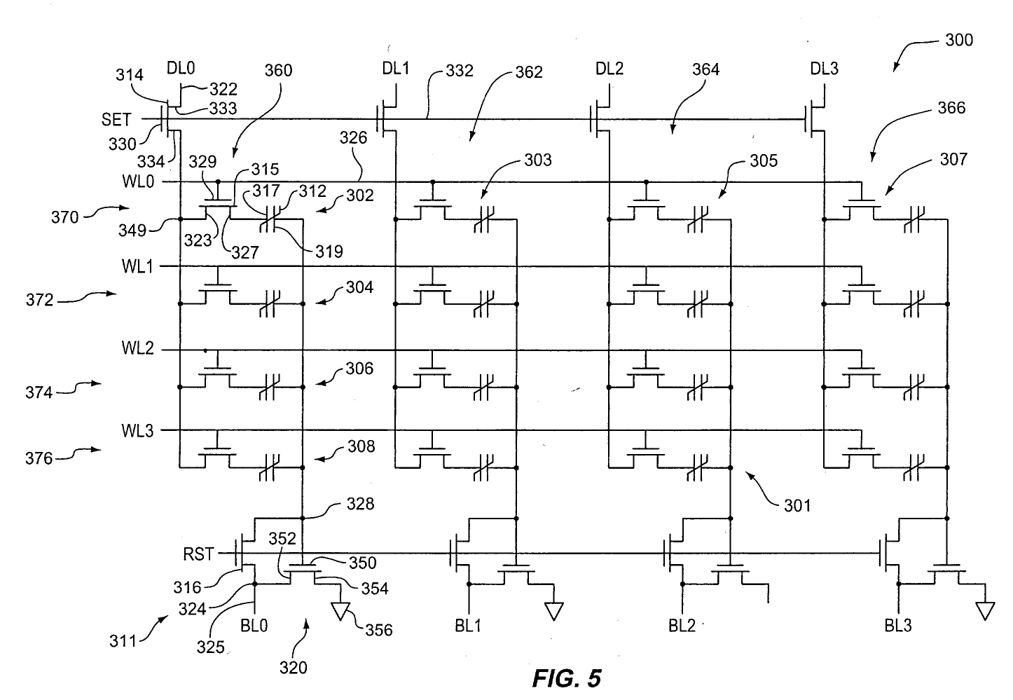

FIG. 5 illustrates a 4×4 link cell architecture. This architecture is similar to that of the chain cell architecture of FIG. 4, except that the transistor and ferroelectric capacitor in each cell are connected in series and the cells in each column are connected in parallel. For example, in cell 302, gate 329 of transistor 315 is connected to word line 326, one source-drain 323 is connected to node 349, and the other source-drain 327 is connected to one electrode 317 of capacitor 312. The other electrode 319 of capacitor 312 is connected to node 328. SET switch 314 is a transistor having its gate 330 connected to SET line 332, one source-drain 333 connected to drive line 322, and the other source-drain 334 connected to node 349. Similarly, reset switch 316 is a transistor 316 connected between bit line node 324 and node 328 as previously described with respect to FIGS. 1 and 4, and preamplifier 320 is a transistor 320 with its gate 350 connected to node 328, one source-drain 352 connected to bit line 325, and the other source-drain 354 connected to ground 356. Again, array system 300 has a cellular array 301 comprising four rows 370, 372, 374, and 376 and four columns 360, 362, 364, and 366 of memory cells. For example, column 360 includes cells 302, 304, 306, and 308, and row 370 includes cells 302, 303, 305, and 307.

The operation of the linked cell structure of FIG. 5 is similar to that of the chain cell structure of FIG. 4, except that, in this architecture, the selected word line signal, such as WL0, is high, turning on the selected transistor, such as 315, while the word line signals of the non-selected rows are low, turning off the corresponding transistor.

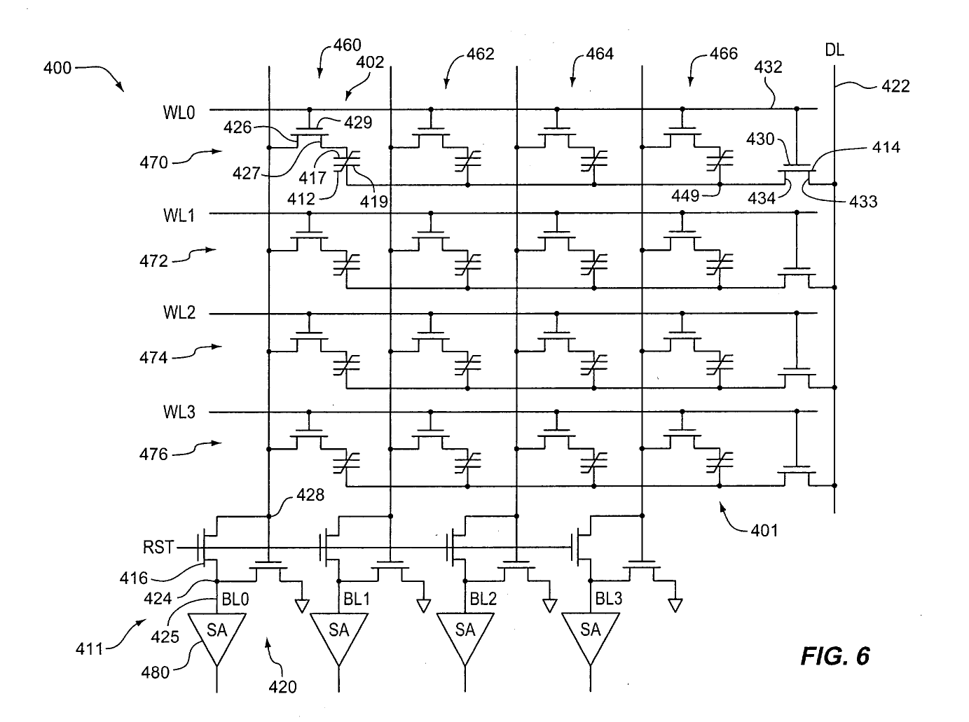

FIG. 6 shows an implementation of an array system 400 in which the basic memory cell, such as 402, has one transistor, such as 415, and one capacitor, such as 412, connected in series. One source-drain 426 of transistor 415 is connected to node 428, while the other source drain 427 is connected to one electrode 417 of capacitor 412. The other electrode of capacitor 412 is connected to drive line node 449. The foregoing is conventionally referred to as a 1T-1C architecture. Like the other systems, system 400 includes an array 401 of cells in four rows 470, 472, 474, and 476, and four columns, 460, 462, 464, and 466. However, the architecture of array system 400 is different from the conventional 1T-1C architecture in that node 449 is connected to drive line 422, which is sometimes called the “plate line” in conventional 1T-1C architecture, via set switch 414, which in this embodiment is set transistor 414. One source-drain 434 of set transistor 414 is connected to node 449, and the other source-drain 433 is connected to drive line 422. In this embodiment, the SET signal is the same as the word line signal WL. For example, gate 430 of set transistor 414 is connected to word line 432. In this embodiment, reset switch 416 is also a transistor 416, and preamplifier 420 is a transistor 420, with switch 416 and preamplifier 420 connected between bit line node 424 and cell/preamplifier node 428 as described above with respect to the other embodiments. In this embodiment, a sense amplifier, such as 480, is shown connected to each bit line, such as 425. Preferably, such a sense amplifier is associated with each bit line in the embodiments of FIGS. 1, 2, 4, and 5, though this was not shown for simplicity.

The operation of the array system 400 of FIG. 6 is the same as the operation of the system of FIG. 5, except either the DL signals become the BL signals, and vice-versa, or what is considered a digital “1” and “0” is reversed. In addition, instead of having a different signal DL for each column and all the set transistors on or off at the same time, there is one DL signal for all cells, and each set switch is independently controlled by the word line. This combination still allows one to control the set signal applied to each group of four cells, though, in this case, the four are a row of cells rather than a column. From the above, one skilled in the art can easily deduce the operation of array system 400 of FIG. 6, so we will not repeat the operation here.

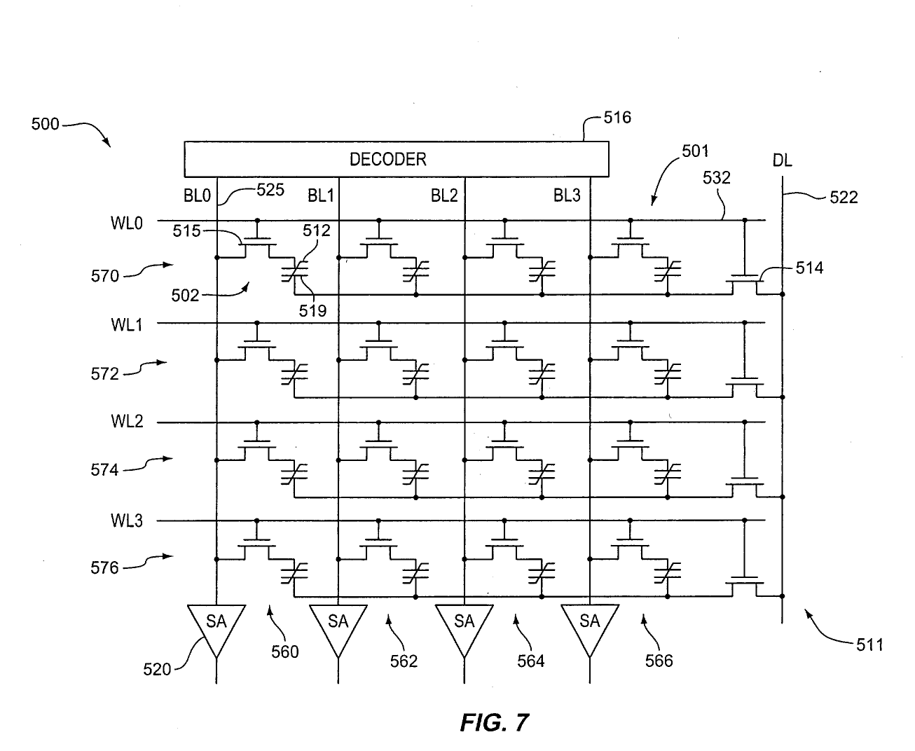

FIG. 7 is a 1T-1C cell implementation of a memory cell array system 500 in which the RST signal is applied via a decoder 516. In this embodiment, the preamplifier is the capacitance of bit line 525, which acts as a voltage divider in the architecture shown, which illustrates another possible variation. Except for these differences, the embodiment is the same as that of FIG. 6. That is, there is an array 501 of memory cells arranged in four rows 570, 572, 574, and 576 and four columns 560, 562, 564, and 566; each cell, such as 502, includes a transistor, such as 515, and a ferroelectric capacitor, such as 512 connected in series; there is a set switch, such as 514, connected between the drive or plate line 522 and one electrode, such as 519, or each capacitor 512, with one set switch 514 associated with each row of cells. The SET signal is applied through word line 532, and reset switches in decoder 516 determine the voltage applied via the bit lines, such as 525, to the memory cells, such as 502. The operation of array system 500 is the same as that of system 400, except the operations of the reset switch and preamplifier are performed by different elements as noted above.

In this disclosure, the terms “row” and “column” are relative terms that are used to facilitate the disclosure. That is, conventionally, a row is a horizontal line or alignment and a column is a vertical line or alignment. However, the invention contemplates that in any array rows can become columns and columns can become rows simply by viewing the array from a perspective that is rotated by 90°, 270°, etc. Thus, because a memory architecture is rotated by 90°, 270°, etc., from the invention described in the Summary Of The Invention, the specification, or the claims herein, but otherwise is the same, does not take it outside of the architectures contemplated by the invention.

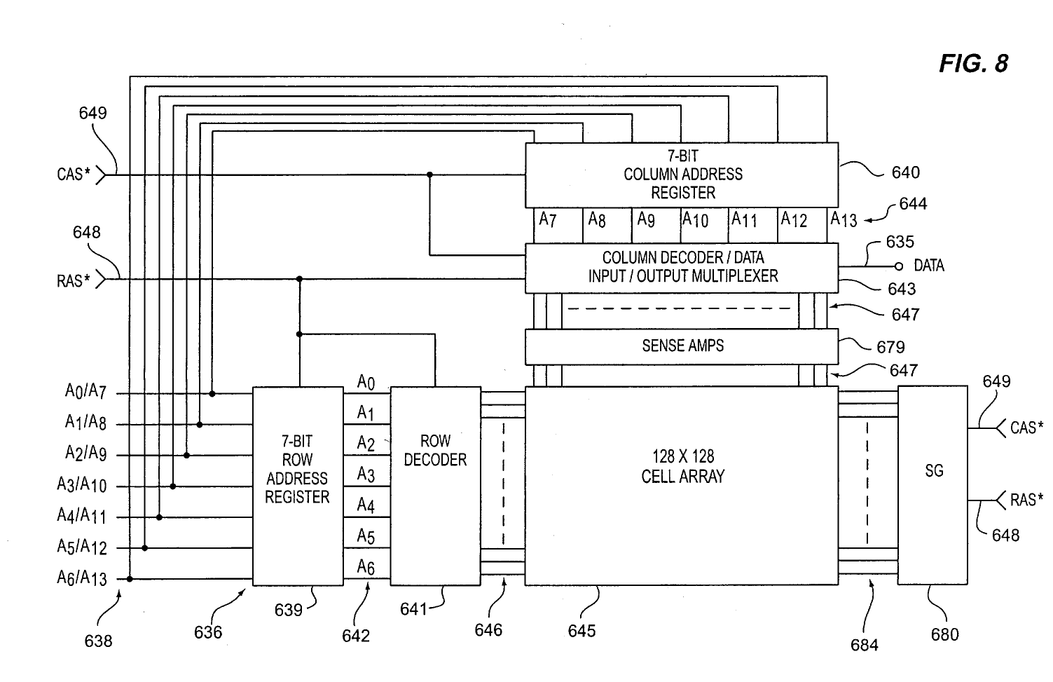

FIG. 8 is a block diagram illustrating an exemplary integrated circuit memory 636 in which memory array systems, such as 200, 300, 400, and 500, according to the invention are utilized. For simplicity, the embodiment shown is for a 16K×1 FERAM; however, the material may be utilized in a wide variety of sizes and types of memories. In the 16K embodiment shown, there are seven address input lines 638 which connect to a row address register 639 and a column address register 640. The row address register 639 is connected to row decoder 641 via seven lines 642, and the column address register 640 is connected to a column decoder/data input/output multiplexer 643 via seven lines 644. The row decoder 641 is connected to a 128×128 memory cell array 645 via 128 lines 646, and the column decoder/data input/output multiplexer 643 is connected to the sense amplifiers 679 and memory cell array 645 via 128 lines 647. A signal generator 680 is connected to the array 645 via up to 256 lines 684. As these lines are the shunt and plate lines discussed above, the number of lines depends on which embodiment of the invention discussed above is utilized. For example, if a common plate line is used for all cells and a separate shunt line is used for each row, then only 129 lines 684 would be required. A RAS signal line 648 is connected to row address register 639, row decoder 641, column decoder/data input/output multiplexer 643, and signal generator 680, while a CAS signal line 649 is connected to column address register 640, column decoder/data input/output multiplexer 643, and signal generator 680. (In the discussion herein, an indicates the inverse of a signal.) An input/output data line 635 is connected to column decoder/data input/output multiplexer 643. Memory 636 also includes a power source 699 that provides the nominal output voltage Vcc and other power to signal generator 680 and the rest of the system as required.

Memory cell array 645 contains 128×128=16,384 memory cells, which is conventionally designated as 16K. These cells are ferroelectric element-based cells such as 202, 302, 402, 502, etc. Lines 646 are the word lines, such as 126, 326, 432, etc. Lines 647 are the bit lines, such as 325, 425, 525, etc.

The operation of the memory in FIG. 8 is as follows. Row address signals A₀ through A₆ and column address signals A₇ through A₁₃ placed on lines 638 are multiplexed by address registers 639, 640 utilizing the RAS and CAS signals, and passed to row decoder 641 and column decoder/data input/output multiplexer 643, respectively. Row decoder 641 places the word line signals, such as the WLn signals discussed above, on one of the word lines 646; generally, a signal is placed on the word line of the cell that is addressed. Column decoder/data input/output multiplexer 643 either places the data signal which is input on line 635 on the one of the bit lines 647 corresponding to the column address, or outputs on the data line 635 the signal on the one of the bit lines 647 corresponding to the column address, depending on whether the function is a write or read function. This is the bit line signal, such as the BLm signal discussed above. As is known in the art, the read function is triggered when the RAS* signal precedes the CAS* signal, and the write function is triggered when the CAS* signal comes before the RAS signal. As is well known in the art, sense amplifiers 679 are located along lines 647 to amplify the signals on the lines. The shunt line and plate line signals, such as SLn and CPn signals discussed above, are produced by signal generator 680 based on the CAS* and RAS* signals and an internal chip clock. Thus, signal generator 680 forms part of shunt systems 11, 101, and 701. In some memories, signal generator 680 and row decoder 641 may be combined into a single signal generation unit. The circuitry of row decoder 641 and signal generator 680 includes all circuitry required to produce the word line, shunt line, and plate line signals discussed above, including the boosted signals. This circuitry is known in the art of integrated circuit memory design, and will not be further discussed herein. Other logic required or useful to carry out the functions outlined above, as well as other known memory functions, is also included in memory 636 but is not shown or discussed, as it is not directly applicable to the invention.

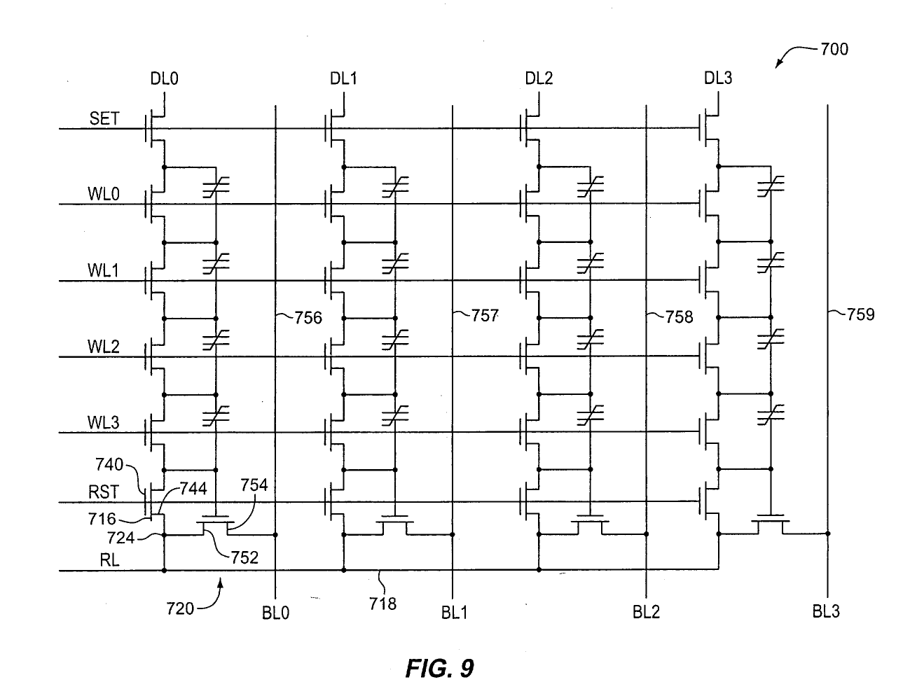

FIG. 9 illustrates an alternative architecture of the memory of FIG. 4 in which the signals that operate the read and write functions are more separated. This embodiment is the same as the embodiment of FIG. 4, except for the following differences: an RL signal is provided on an additional line 718; reset switch 740 has one source-drain 744 connected to line 718; preamplifier 720 has one source-drain connected to line 718 and the other source-drain 754 connected to bit line 756. Similarly, line 718 is connected to each of the other reset switches, and each of the other rows of cells has an associated bit line 757, 758, and 759 that carries a signal BL1, BL2, and BL3, respectively, that is separate from the RL signal. The reading and writing functions in this embodiment are the same as those for the embodiment of FIG. 4, except for the separation of the RL and BL signals. The alternative architecture and signals shown in the embodiment of FIG. 9 can also be applied to the array systems of FIGS. 5, 6, and 7, or any other appropriate architecture with which the invention is used.

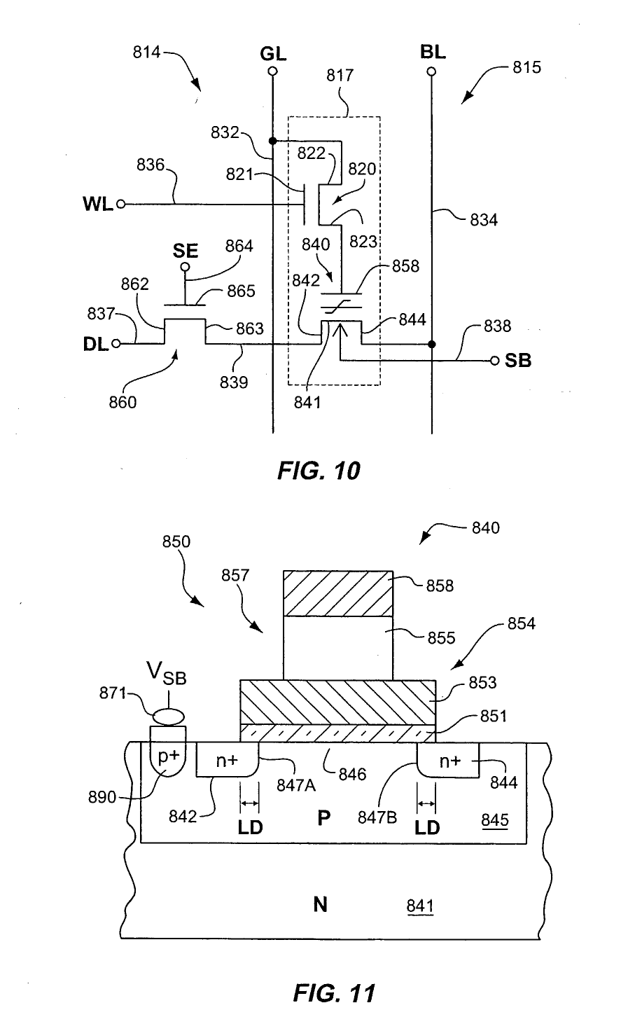

Directing attention to FIG. 10, a simplified, one-cell memory 814 according to an alternative embodiment of the invention is shown for illustrative purposes. Memory 814 includes memory array 815, a read transistor 860, a select line 864, and a drain line input 837. Memory array 815 includes a memory cell 817, a gate line 832, a bit line 834, a word line 836, a substrate line 838, and a drain line 839. Memory cell 817 includes an erase/write switching device 820, and a ferroelectric field effect transistor (FeFET) 840. Erase/write switching device 820 may be a diode, a Schottky diode, a pair of back-to-back diodes or other electronic switch, but preferably is a transistor, which we shall refer to herein as an erase/write transistor 820. Transistor 820 is referred to as an “erase/write” switching device to indicate that it functions during the erase and write operations, but does not function during the read operation. Transistor 820 is preferably a conventional transistor such as a MOSFET. Read transistor 860, which is a conventional transistor, and preferably a MOSFET, forms part of the peripheral address circuitry and is not part of memory cell 817. Word line 836 is connected to gate 821 of write transistor 820. Gate line 832 is connected to one source/drain 822 of transistor 820 and the other source/drain 823 is connected to gate 858 of FeFET 840. One source/drain 842 of FeFET 840 is connected to one source/drain of transistor 860. The other source/drain 844 of FeFET 840 is connected to bit line 834. The other source/drain 862 of transistor 860 is connected to drain line input 837. Select line 864 is connected to gate 865 of transistor 860.

In the operation of memory 814, which shall be discussed in detail below, a signal WL is applied to word line 836, a signal GL is applied to gate line 832, a signal BL is applied to and/or generated on bit line 834, a signal SB is applied to substrate line 838, a signal DL is applied to drain line input 837, and a signal SE is applied to select line 864.

Turning to FIG. 11, a cross-sectional view of a ferroelectric FET (FeFET) 840 illustrating a key aspect of the invention is shown. FeFET 840 is conventionally known as a metal-ferroelectric-metal-insulator-semiconductor (MFMIS) field effect transistor (FET). Another common FeFET that may be used is a metal-ferroelectric-insulator-semiconductor FeFET (MFISFET). Many other types of FeFETs may be used. FeFET 840 includes a substrate 841 which is preferably n-type silicon, but may be p-type silicon or any other appropriate semiconductor, such as gallium arsenide, silicon germanium, and others. A well 845, preferably a p-type well, is formed within substrate 841. As will be discussed further below, substrate 841 is preferably undoped or very lightly doped so that it acts essentially as a substrate insulator, which insulates well 845 from other wells in the substrate. Doped active areas 842, 844, and 890 are formed in well 845. Active areas 842 and 844 are preferably n-type. We shall generally refer to these active areas 842 and 844 herein as source/drains, since they can either be a source or a drain depending on the relative voltages applied to the areas. In certain portions of this disclosure, the voltages applied to these areas indicate that one is a source and the other is a drain; in these portions, we will then refer to them specifically as either a source or a drain. Active area 890 is preferably highly doped p-type and forms the contact area for the dedicated substrate conductor 871, which preferably is a wiring material, such as aluminum. A channel region 846, preferably also n-type, but not as highly doped as source/drains 842 and 844, is formed between source/drains 842 and 844. A gate structure 850 is formed on substrate 841 above channel region 846. In the preferred embodiment, gate structure 850 is a multilayer structure, though it may not include all the layers 851 through 858 shown in FIG. 10, and may include additional layers as known in the art. That is, gate structure 850 shown in FIG. 11 is intended to illustrate the layers that could be included in the structure. The fundamental layers involved are an insulating layer 851, a floating gate layer 853, sometimes referred to herein as the lower gate electrode, a ferroelectric layer 855, and a gate electrode layer 858, sometimes referred to herein as the upper gate electrode. Insulating layer 851, often referred to as the “gate oxide”, may be a multilayer structure, each layer of which is a different insulator. It may include an insulator closely related to the material of semiconductor 841; a buffer layer that can perform one or both of two functions, i.e., assisting in the adhesion of the layers above it to the layer below it, and preventing the migration of elements in the layers above it to the layers below it; and another material having dielectric properties suitable for effective operation of the FeFET. A floating conducting gate 853 is formed on insulating layer 851. Again, the floating gate may include multiple layers. A ferroelectric layer 855 is formed on floating gate 852. A gate electrode 858 is formed on ferroelectric layer 855. It should be understood that ferroelectric layer 855 and gate electrode 858 can also be multilayer structures, though generally they are not. Wiring layers (see FIG. 4) form electrical contacts to source/drains 842, 844, gate electrode 858, and p-well 845. It should be noted that a ferroelectric FET is essentially a pair of capacitors 857 and 854 in series. In this context, gate electrode 858 is the top electrode of ferroelectric capacitor 857, and substrate well 845 acts as the bottom electrode of gate capacitor 854. As will be discussed further below, substrate well 845 also acts as a virtual bottom electrode of ferroelectric capacitor 857, since the voltage across ferroelectric 855 is determined by the voltage on top electrode 858 and substrate well 845. As shown in the drawing, in the preferred embodiment, the area of capacitive element 854 comprising floating gate 853 and gate insulator 851 is greater than the area of capacitive element 857 comprising ferroelectric layer 855 and gate electrode 858 to enhance the voltage drop across ferroelectric 855.

It should be understood that FIG. 11 depicting an integrated circuit device is not meant to be actual plan or cross-sectional views of any particular portion of an actual integrated circuit device. In the actual devices, the layers will not be as regular and the thicknesses will generally have different proportions. This figure and other such figures instead show idealized representations which are employed to more clearly and fully depict the structure and process of the invention than would otherwise be possible. For example, if the various thicknesses of the layers were correct relative to one another, the drawing of the FeFET could not fit on the paper.

Terms of orientation herein, such as “above”, “over”, “top”, “upper”, “below”, “bottom”, and “lower”, mean relative to semiconductor substrate 841. That is, if a second element is “above” a first element, it means it is farther from substrate 841; and if it is “below” another element, then it is closer to substrate 841 than the other element. The long dimension of substrate 841 defines a substrate plane that is defined by the horizontal direction and the direction into and out of the paper in FIG. 11. Planes parallel to this plane are called a “horizontal” plane herein, and directions perpendicular to this plane are considered to be “vertical”. A memory cell typically comprises relatively flat thin film layers. The terms “lateral” or “laterally” refer to the direction of the flat plane of the thin film layers. In FIG. 11, the lateral direction would be the horizontal direction. The terms “underlie” and “overlie” are also defined in terms of substrate 841. That is, if a first element underlies a second overlying element, it means that a line perpendicular to the substrate plane that passes through the first element also passes through the second element. The term “between” does not mean that the buffer layer is in direct contact with the thin film of ferroelectric material or the semiconductor. The layer “between” other layers may contact the layers it is between, but typically, it does not. The term “on” is sometimes used in the specification when referring to the deposition or formation of an integrated circuit layer or element onto an underlying substrate or layer. When this term is used, it usually means that at least a portion of the overlying layer is formed directly in contact with the underlying layer. For example, when we say that FET 840 is formed on well 845, it means that at least gate insulator 851 overlies and is in direct contact with well 845.

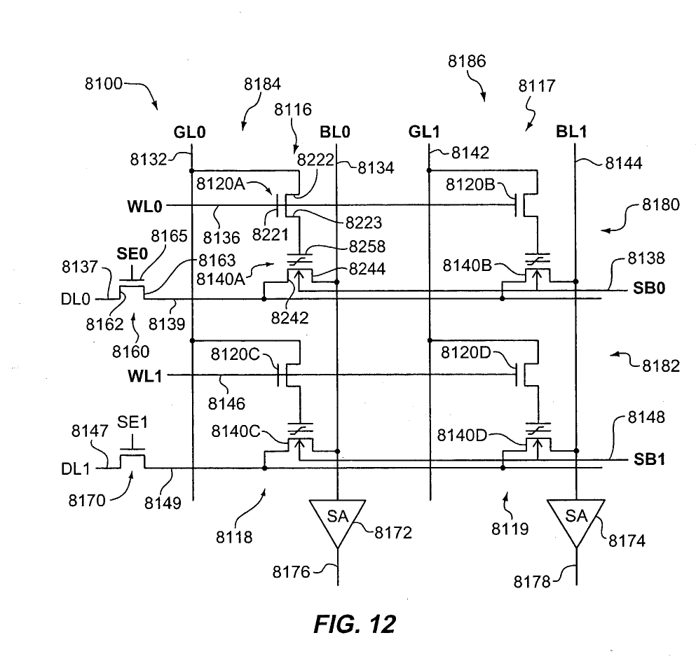

Turning to FIG. 12, a 2×2 memory array 100 including four memory cells 116, 117, 118, and 119 is shown. Each memory cell is identical in architecture to memory cell 817 discussed above, including a conventional transistor, such as 8120A, and a ferroelectric FET (FeFET), such as 8140A. A 2×2 array is shown because it is the simplest array with which all of the possible effects on neighboring cells when a cell is erased, written to, or read can be shown. However, an actual memory array will be much larger, including perhaps a thousand rows and a thousand columns. As is conventional in the art, each cell in the memory holds one bit of data, and all the cells in a row hold a byte of data. In array 8100, there are two bits to a byte. Memory 8100 has two rows of cells, i.e., bytes 8180 and 8182, and two columns of cells, i.e., columns 8184 and 8185. Array 8100 includes two gate lines, 8132 and 8142, two bit lines, 8134 and 8144, two word lines, 8136 and 8146, two drain inputs, 8137 and 8147, two drain lines, 8139 and 8149, and two substrate lines, 8138 and 8148. Drain inputs 8137 and 8147 represent a source of a current. Word line 8136 is connected to the gate, such as 8221, of each write transistor in byte 8180, and similarly, word line 8146 is connected to the gate of each write transistor in byte 8182. Gate line 8132 is connected to one source/drain, such as 8222, of each write transistor, such as 8120A, in column 8184, while gate line 8142 is similarly connected to one source/drain of each write transistor in column 8186. In each memory cell, the other source drain, such as 8223, of the write transistor is connected to the gate, such as 8258, or the FeFET, such as 8140A. Bit line 8134 is connected to one source/drain, such as 8244, of each FeFET in column 8184, while bit line 8144 is connected to one source/drain of each FeFET in column 8186. Drain line 8139 is connected to the other source/drain, such as 8242, or each FeFET in row 8180, while drain line 8149 is connected to each of the other source/drains of each FeFET in row 8182. Substrate line 8138 is connected to the substrate such as 8241 (FIG. 5) of each of the FeFETs in row 8180, while substrate line 8148 is connected to the substrate of each of the FeFETs in row 8182. Gate line signal GL0 is applied to gate line 8132 and gate line signal GL1 is applied to gate line 8142. Bit line signal BL0 is applied to bit line 8134 and bit line signal BL1 is applied to gate line 8144. Substrate signal SB0 is applied to substrate line 8138, while substrate signal SB1 is applied to substrate line 8148. Reading transistor 8160, preferably a MOSFET, is connected between drain line input 8137 and drain line 8139. The read enable signal for row or byte 8180, SE0, is applied to gate 8165 of transistor 8160. Drain signal DL0 is applied to one source-drain of read transistor 8160, while the other source drain 8163 is connected to drain line 8139. Read transistor 8170, also preferably a MOSFET, is connected between drain line input 8147 and drain line 8149. The read enable signal for the row or byte 8182, SE1, is applied to the gate of transistor 8170. Drain signal DL1 is applied to one source/drain of read transistor 8170, while the other source/drain is connected to drain line 8149. Sense amplifier 8172 is connected to bit line 8134 and provides output data on line 8176, while sense amplifier 8174 is connected to bit line 8144 and provides output data on line 8178.

The operation of a memory according to the invention will be described in conjunction with Truth Tables 2-6. Before writing data to a cell, the cell should preferably be erased, which, with the conventions selected, is the same as resetting to a logic “0”. To reset byte 8180 to a logic “0”, that is, to erase the data in cells 8116 and 8117, WL0 is set at 5V, which turns write transistors 8120A and 8120B on. This permits the 0V PL0 and GL1 signals to pass to the gates of FeFETs 8140A and 8140B. SB0 is set at 5V. With the substrate at 5V and the gate at 0V, the ferroelectric will be polarized such that a logic “0” will be written into cells 8116 and 8117. With SE0 and SE1 at 0V, transistors 8160 and 8170 will be off, and it does not matter what the DL0 and DL1 signals are, though preferably they will be at 0V. BL0 is set to 5V also to prevent the PN junction at the interface (see 847B in FIG. 11) of the source and channels of FeFETs 8140A and 8140B, such as at the interface of source 8244 and channel 8246, from becoming forward-biased. WL1, SE1, and SB1 are all set to 0V so that in cells 8118 and 8119 every electronic element is at 0V, except for the drains of the FeFETs 8140C and 8140D. Since the PN junction at the channel-source interface is reversed biased, the voltage in the channel will be close to the substrate voltage, i.e., 0V. Since the gate is floating, this will not cause a disturb. This is particularly true if the lateral diffusion length, shown as LD in FIG. 11, is small. In state-of-the-art FeFET processing, LD generally is minimal or even zero, so there will be no disturb. Use of the design of FIG. 11 in which the ferroelectric is well removed from the active areas further ensures that there will be no chance of a disturb occurring.

Summarizing the above, the signals required to reset any cell to a logic “0” are shown in Truth Table 3. All other signals will be 0V. Thus, as seen above, only the selected cells will be reset to a logic “0”, and the non-selected cells will not be disturbed.

As can be seen from FIG. 12, block reset or block erase is also available with the architecture according to the invention. That is, any byte for which WL is set to 5V will be reset. If block reset is intended to be used, all of the FeFETs are preferably fabricated in the same well so that their substrates are connected. That is, in terms of FIG. 12, substrate lines 8138 and 8148 are connected. This operation mode is useful for applications in which the FeFET memory is intended to replace flash memory.

TRUTH TABLE 3
RESET CELL TO LOGIC “0”

| Signal | Voltage |
|---|---|
| WL | 5 V |
| GL | 0 V |
| SB | 5 V |
| SE | 0 V |
| BL | 5 V |
| DL | Don't Care |

To write a logic “1” to cell 8116 and a logic “0” to cell 8117, WL0 is set at 5V, which turns write transistors 8120A and 8120B on, which permits the 5V PL0 and 0V GL1 signals to pass to the gates of FeFETs 8140A and 8140B, respectively. All the other signals are set at 0V. With the substrate at 0V and the gate at 5V, the ferroelectric of cell 8116 will be polarized such that a logic “1” will be written into the cell. With SEQ and SE1 at 0V, transistors 8160 and 8170 will be off, and it does not matter what the DL0 and DL1 signals are, though preferably they will be at 0V. Thus, for cells 8117, 8118, and 8119, every electronic element is at 0V, and these cells will not be disturbed. Since cell 8117 is not disturbed, it remains at the logic “0” to which it was reset in the erase operation described above.

Summarizing the above, the signals required to write any cell to a logic “1” are shown in Truth Table 4. All other signals will be 0V. Thus, as seen above, only the selected cells will be written to a logic “1”.

TRUTH TABLE 4
WRITE CELL TO LOGIC “1”

| Signal | Voltage |
|---|---|
| WL | 5 V |
| GL | 5 V |
| SB | 0 V |
| SE | 0 V |
| BL | 0 V |
| DL | Don't Care |

To read byte 8180 in a first embodiment of the read function, WL0 and WL1 are set at 0V, which turns write transistors 8120A through 8120D off. SEQ is set to 5V, which turns transistor 8160 on, while SE1 is set to 0V, which keeps transistor 8170 off. DL0 is set to 0V. DL1 does not matter, but, preferably, it is also set to 0V. BL0 and BL1 are preferably initially set to 0.5V. All the other signals are set at 0V. In each cell, both the gate and substrate are at the same voltage, i.e., 0V, so no cell is disturbed. If, for example, cell 8116 is in the logic “1” state, channel 8246 in FeFET 8140A will be conducting and current will flow from bit line 8134 to the drain, and bit line 8134 will fall to ground. Sense amplifier 8172 will detect this fall of voltage and output a logic “1” on data line 8176. On the other hand, if cell 8116 is in the logic “0” state, channel 8246 will be non-conducting and bit line 8134 will remain at 0.5V. Sense amplifier 8176 will detect this voltage and output a logic “0” on data line 8176. Similarly, sense amplifier 8174 will sense the logic state of cell 8117 and output the corresponding data on line 8178.

In the above-read embodiment, the drain input can always be grounded, which enables an architecture which reduces the area of the layout even further. It is noted that the bit line corresponding to the cells to be read is placed at a low voltage, such as 0.5V, to prevent any disturb to the cells when they are read. Since the PN junction at the channel-source interface is reverse biased, the voltage in the channel will be essentially the substrate voltage, i.e., 0V. If the lateral diffusion length, shown as LD in FIG. 11, is small, the 0.5V on the source will not be sufficient to disturb cells 8118 or 8119, since the gate is floating, and particularly if the FeFET design of FIG. 11 is used. Simulations have shown that this is true even if the read operation is performed 1010 times between write operations.

Summarizing the above, the signals required to read any cell in the above embodiment are shown in Truth Table 5. All other signals will be 0V. Thus, as seen above, only the selected cells will be read, and no cells will be disturbed.

TRUTH TABLE 5
READ (first embodiment)

| Signal | Voltage |
|---|---|
| WL | 0 V |
| GL | 0 V |
| SB | 0 V |
| SE | 5 V |
| BL | 0.5 V, Sense logic state |
| DL | 0 V |

To read byte 8180 in a second embodiment of the read function, WL0 and WL1 are set at 0V, which turns write transistors 8120A through 8120D off. SEQ is set to 5V, which turns transistor 8160 on, while SE1 is set to 0V, which keeps transistor 8170 off. DL0 is set to 0.5V. DL1 does not matter, but, preferably, it is set to 0V. BL0 and BL1 are preferably initially set to 0V. All the other signals are set at 0V. In each cell, both the gate and substrate are at the same voltage, i.e., 0V, so no cell is disturbed. If, for example, cell 8116 is in the logic “1” state, channel 8246 in FeFET 8140A will be conducting and current will flow from drain input 8137 to bit line 8134 and the bit line will rise to near 0.5V. Sense amplifier 8172 will detect this rise of voltage and output a logic “1” on data line 8176. On the other hand, if cell 8116 is in the logic “0” state, channel 8246 will be non-conducting and bit line 8134 will remain at 0V. Sense amplifier 8176 will detect this voltage and output a logic “0” on data line 8176. Similarly, sense amplifier 8174 will sense the logic state of cell 8117 and output the corresponding data on line 8178.

In the above-read embodiment, the drain input can always be set at 0.5V, which may reduce the area of the layout. Similar to the first read embodiment, the drain of the cells to be read is placed at a low voltage, such as 0.5V, to prevent any disturb to the cells when they are read. Since the PN junction at the drain-channel interface (see 847A in FIG. 11) is reverse biased, the voltage in the channel will be essentially the substrate voltage, i.e., 0V. If the lateral diffusion length, shown as LD in FIG. 11, is small, the 0.5V on the drain will not be sufficient to disturb cells 8118 or 8119, since the gate is floating, and particularly if the FeFET design of FIG. 11 is used. Simulations have shown that this is true even if the read operation is performed 10¹⁰ times between write operations.

Summarizing the above, the signals required to read any cell in the above embodiment are shown in Truth Table 6. All other signals will be 0V. Thus, as seen above, only the selected cells will be read, and no cells will be disturbed.

TRUTH TABLE 6
READ (second embodiment)

| Signal | Voltage |
|---|---|
| WL | 0 V |
| GL | 0 V |
| SB | 0 V |
| SE | 5 V |
| BL | 0 V, Sense logic state |
| DL | 0.5 V |

In all of the above embodiments, it should be understood that the voltages WL, GL, BL, DL, SB, and SE can be varied from those given for design convenience for reducing disturb, if necessary. It also should be understood that the logic state can be sensed by a current sense amplifier as well as a voltage sense amplifier. It should also be understood that either n-channel transistors, p-channel transistors, or a combination of the two can be used.

An important feature of the invention is that the opportunity for disturb of the data in cells is dramatically reduced. If block erase of the entire memory is used, there is no realistic chance of disturb. The only time when a voltage other than an erase or write voltage is placed across the ferroelectric material is during the read cycle. This voltage is very small and is reduced further by the fact that it is placed only on the source of the FeFET, or only on the drain, the gate is floating at the time the voltage exists, and a reverse bias exists between the channel and source/drain that holds the voltage. Present-day ferroelectric materials, such as layered superlattice materials, will disturb about every thousand cycles if 0.4V is placed across the ferroelectric. However, the chances of disturb fall off dramatically as the voltage is decreased below 0.4V. At a 0.2V voltage across a ferroelectric, there will be no disturb even after 10¹⁰ to 10¹¹ cycles. SPICE simulations of the memory according to the invention show that the voltage across the ferroelectric under the read conditions described above will be even less than 0.2V. Thus, the memory according to the invention is, for all practical purposes, disturb free.

Another important feature of the invention is that the memory operates well with much lower ferroelectric polarizabilities than a NVFRAM and other FeFET memories. NVFRAMs require a polarizability of at least 7 microcoulombs/centimeter squared (μC/cm²) for a practical working memory. However, a smaller polarizability will result in a more highly saturated polarization in the ferroelectric at a given polarizing field. The higher saturation results in longer retention times. It has been found that the readout current decreases from 420 microamperes to 340 microamperes when the polarization decreases from 8 μC/cm² to 2 μC/cm². This is a relatively small decrease in readout current for a large increase in saturation. A readout current of 340 microamperes is large enough to be read reliably by state-of-the-art current sense amplifiers. In addition, materials with smaller polarizabilities also often have smaller dielectric constants. Since a ferroelectric FET is essentially a pair of capacitors 857 and 854 in series, the smaller the dielectric constant of a ferroelectric, the larger the voltage that drops across ferroelectric capacitor 857 for a given FeFET design. Thus, the use of materials with smaller polarizabilities also leads to better switching of the ferroelectric for this reason also.

A feature of the invention is that the preamplifier or “read transistor”, such as 42, 840 enables the use of a read voltage much smaller than the prior art. The preamplifier 20, 42, 120, 320, 420, 840 may take many forms other than a transistor; for example, it may be a capacitor that acts as a voltage divider, a diode, a series of gates, or other circuit or circuit element. The voltage applied to the circuit to read a cell, that is, the voltage applied to DL, is about 1.2V, and typically 0.5V to 2.0V. However, the read voltage that an individual cell sees, i.e., the voltage placed across the ferroelectric memory element when it is read, can be as little as 0.1V, and typically is about 0.1V to 0.5V, and most preferably about 0.1V to 0.3V. This voltage is generally one-half or less of the coercive voltage, and in some architectures is one-third or less of the coercive voltage, and most preferably is one-tenth to one-half of the coercive voltage. Since the probability of a disturb occurring decreases exponentially with the voltage applied, a voltage of one-tenth to one-half of the coercive voltage has negligible chance of causing a disturb. Moreover, since the read voltage is so small, its effect on neighboring cells to the one being read is so small as not to be calculable. These small read voltages also greatly reduce the rate of fatigue of an individual cell.

At the same time that the invention is useful in permitting very small disturbances to the memory, it is also useful in increasing the performance of conventional memories such as destructive read out memories. That is, the increased performance that permits detection of small signals also significantly increases the performance and robustness of a memory if it is employed in combination with memories that may have more significant chance of fatigue and disturb. Thus, it will be quite useful in applications in which fatigue and disturb are not a concern because of the small number of cycles, but absolute accuracy of data is critical.

Another feature of the invention is that the different data states are distinguished by different polarization slopes, rather than polarization differences. Thus, high polarization ferroelectrics are not required.

Another feature of the invention is that a single power supply can be used. That is, the read and write voltages are all small positive values. This significantly simplifies the peripheral circuitry required for the memory.

There have been described what are at present considered to be the preferred embodiments of the invention. It will be understood that the invention can be embodied in other specific forms without departing from its spirit or essential characteristics. For example, while the invention has been described in terms of transistor switches, other switches, such as diodes, may be used. Many other ferroelectric memory cell architectures can be used in combination with the addressing scheme shown, for example, those cell architectures disclosed in the references discussed in the Background Of The Invention. Further, now that the possibility and advantages of addressing a ferroelectric memory cell utilizing a set switch and a reset switch in combination with a preamplifier has been disclosed, many modifications and variations of the principles disclosed may be devised. For example, in the embodiments of FIGS. 2, 4, 5, and 6, the source-drain, such as 254, connected to ground may be connected to the bit line, and the other source-drain, such as 252, and the reset switch, such as 116, may be connected to ground. The present embodiments are, therefore, to be considered as illustrative and not restrictive. The scope of the invention is indicated by the appended claims.

1. A method of reading a ferroelectric memory, said memory including: a memory cell including a ferroelectric memory element having a coercive voltage, and a conducting line connected to said memory cell, said method comprising the steps of:
placing a voltage across said ferroelectric memory element, said voltage being less than said coercive voltage; and
sensing a voltage on said conducting line.

2. A method as in claim 1 wherein said voltage ranges from 0.1 volts to 0.5 volts.

3. A method as in claim 1 wherein said voltage ranges from 0.1 volts to 0.3 volts.

4. A method as in claim 1 wherein said voltage is one-half of said coercive voltage or less.

5. A method as in claim 1 wherein said voltage is one-third of said coercive voltage or less.

6. A method as in claim 1 wherein said memory includes a group of memory cells connected to said conducting line and further including a reset step comprising discharging noise from said group of memory cells.

7. A method as in claim 6 wherein each of said memory elements comprises a ferroelectric capacitor and said reset step comprises grounding both sides of each of said ferroelectric capacitors in said group of memory cells.

8. A method of reading a ferroelectric memory, said memory including: a memory cell including a ferroelectric memory element and a conducting line connected to said memory cell, said method comprising the steps of:
placing a first voltage across said ferroelectric memory element to develop a read voltage on said conducting line;
preamplifying said read voltage to produce a preamplified voltage or current on a bit line; and
sensing said preamplified voltage or current on said bit line.

9. A method as in claim 8 wherein said first voltage ranges from 0.1 volts to 0.5 volts.

10. A method as in claim 8 wherein said first voltage ranges from 0.1 volts to 0.3 volts.

11. A method as in claim 8 wherein said first voltage is one-half or less of the coercive voltage of said ferroelectric memory element.

12. A method as in claim 8 wherein said first voltage is one-third or less of the coercive voltage of said ferroelectric memory element.

13. A method of discharging noise from a ferroelectric memory, said memory including a group of memory cells, each memory cell including a ferroelectric capacitor, said method comprising grounding both sides of each of said ferroelectric capacitors.
